(19) United States
(12) Patent Application Publication
(10) Pub. No.: US 2025/0169168 A1
(43) Pub. Date: May 22, 2025

(54) BACKSIDE CONTACT CAP AND SPACER FOR BACKSIDE SIGNAL CONTACT ISOLATION

(71) Applicant: INTERNATIONAL BUSINESS MACHINES CORPORATION, ARMONK, NY (US)

(72) Inventors: Tsung-Sheng Kang, Ballston Lake, NY (US); Tao Li, Slingerlands, NY (US); Ruilong Xie, Niskayuna, NY (US); Nicolas Jean Loubet, GUILDERLAND, NY (US)

(21) Appl. No.: 18/513,765

(22) Filed: Nov. 20, 2023

(51) Int. Cl. H01L 27/088; H01L 29/06; H01L 29/40; H01L 29/417; H01L 29/423; H01L 29/66; H01L 29/775; H01L 29/786

(52) U.S. Cl. CPC H10D 84/83; H10D 30/014; H10D 30/43; H10D 30/6735; H10D 30/6757; H10D 62/121; H10D 64/01; H10D 64/254; H10D 64/518

(57) ABSTRACT

A microelectronic structure a first nanosheet transistor that includes a first source/drain, and a second nanosheet transistor that is adjacent to the first nanosheet transistor. The second nanosheet transistor includes a second source/drain. A shared gate that extends between the first nanosheet transistor and the second nanosheet transistor. A gate protrusion that extends towards a backside region of the first nanosheet transistor and the backside region of the second nanosheet transistor. A first backside contact connected to first source/drain and a second backside contact connected to the second source/drain. A signal contact connected to the gate protrusion. An isolation layer located between the signal contact and first backside contact and the isolation layer is located between the signal contact and the second backside contact.

### BACKGROUND

The present invention generally relates to the field of microelectronics, and more particularly to the formation a backside gate contact.

Nanosheet is the lead device architecture in continuing CMOS scaling. However, nanosheet technology has shown issues when scaling down such that as the devices become smaller and closer together, they are interfering with each other. With the number of devices being fitted in a smaller area it is becoming harder to form separate backside contacts that have enough surface contact with the source/drains.

### BRIEF SUMMARY

Additional aspects and/or advantages will be set forth in part in the description which follows and, in part, will be apparent from the description, or may be learned by practice of the invention.

A microelectronic structure a first nanosheet transistor that includes a first source/drain, and a second nanosheet transistor that is adjacent to the first nanosheet transistor. The second nanosheet transistor includes a second source/drain. A shared gate that extends between the first nanosheet transistor and the second nanosheet transistor. A gate protrusion that extends towards a backside region of the first nanosheet transistor and the backside region of the second nanosheet transistor. A first backside contact connected to first source/drain and a second backside contact connected to the second source/drain. A signal contact connected to the gate protrusion. An isolation layer located between the signal contact and first backside contact and the isolation layer is located between the signal contact and the second backside contact.

A microelectronic structure a first nanosheet transistor that includes a first source/drain, and a second nanosheet transistor that is adjacent to the first nanosheet transistor. The second nanosheet transistor includes a second source/drain. A shared gate that extends between the first nanosheet transistor and the second nanosheet transistor. A gate protrusion that extends towards a backside region of the first nanosheet transistor and the backside region of the second nanosheet transistor. A first backside contact connected to the first source/drain and a second backside contact connected to the second source/drain. A first metal line connected to the first backside contact and a second metal line connected to the second backside contact. A signal contact connected to the gate protrusion. An isolation layer located between the signal contact and first backside contact and the isolation layer is located between the signal contact and the second backside contact.

A method includes the steps of forming a first nanosheet transistor that includes a first source/drain, and forming a second nanosheet transistor that is adjacent to the first nanosheet transistor. The second nanosheet transistor includes a second source/drain. Forming a shared gate that extends between the first nanosheet transistor and the second nanosheet transistor. Forming a gate protrusion that extends towards a backside region of the first nanosheet transistor and the backside region of the second nanosheet transistor. Forming a shared backside contact separating the shared backside contact into a first backside contact connected to first source/drain and a second backside contact connected to the second source/drain. Forming a first isolation layer segment adjacent to the first backside contact and forming a second isolation layer segment adjacent to the second backside contact. Forming a signal contact connected to the gate protrusion, wherein the signal contact is located between the first isolation layer segment and the second isolation layer segment.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of nanosheet transistors, in accordance with the embodiment of the present invention.

FIG. 2 illustrates a cross section X of the nanosheet transistor after the formation of a first hardmask, and a first lithography layer on top of the alternating layers, and the patterning of the first lithography layer to form the gate protrusion trench, in accordance with the embodiment of the present invention.

FIG. 3 illustrates a cross section Y1 of the source/drain region after the formation of a first hardmask, and a first lithography layer on top of the alternating layers, and the patterning of the first lithography layer to form the gate protrusion trench, in accordance with the embodiment of the present invention.

FIG. 4 illustrates a cross section Y2 of the gate region after the formation of a first hardmask, and a first lithography layer on top of the alternating layers, and the patterning of the first lithography layer to form the gate protrusion trench, in accordance with the embodiment of the present invention.

FIG. 5 illustrates a cross section X of the nanosheet transistor after the removal of the first lithography layer and the removal of the first hardmask and the formation of a dummy gate, in accordance with the embodiment of the present invention.

FIG. 6 illustrates a cross section Y1 of the source/drain region after the removal of the first lithography layer and the removal of the first hardmask and the formation of a dummy gate, in accordance with the embodiment of the present invention.

FIG. 7 illustrates a cross section Y2 of the gate region after the removal of the first lithography layer and the removal of the first hardmask and the formation of a dummy gate, in accordance with the embodiment of the present invention.

FIG. 8 illustrates a cross section X of the nanosheet transistor after the formation of a second hardmask, removal of the first sacrificial layer, formation of the gate spacer and the bottom dielectric isolation layer, patterning of the nano stacks to form the source/drain regions, recessing of the sacrificial layers, and formation of the inner spacer, in accordance with the embodiment of the present invention.

FIG. 9 illustrates a cross section Y1 of the source/drain region after the formation of a second hardmask, removal of the first sacrificial layer, formation of the gate spacer and the bottom dielectric isolation layer, patterning of the nano stacks to form the source/drain regions, recessing of the sacrificial layers, and formation of the inner spacer, in accordance with the embodiment of the present invention.

FIG. 10 illustrates a cross section Y2 of the gate region after the formation of a second hardmask, removal of the first sacrificial layer, formation of the gate spacer and the bottom dielectric isolation layer, patterning of the nano stacks to form the source/drain regions, recessing of the sacrificial layers, and formation of the inner spacer, in accordance with the embodiment of the present invention.

FIG. 11 illustrates a cross section X of the nanosheet transistor after the formation of placeholders and the formation of the source/drains, in accordance with the embodiment of the present invention.

FIG. 12 illustrates a cross section Y1 of the source/drain region after the formation of placeholders and the formation of the source/drains, in accordance with the embodiment of the present invention.

FIG. 13 illustrates a cross section X of the nanosheet transistor after formation of a frontside interlayer dielectric layer, removal of the second hardmask, the dummy gate, and the sacrificial layers, formation of a gate, formation of frontside contacts, back-end-of-the-line (BEOL) layer, and the carrier wafer, in accordance with the embodiment of the present invention.

FIG. 14 illustrates a cross section Y1 of the source/drain region after formation of a frontside interlayer dielectric layer, removal of the second hardmask, the dummy gate, and the sacrificial layers, formation of a gate, formation of frontside contacts, back-end-of-the-line (BEOL) layer, and the carrier wafer, in accordance with the embodiment of the present invention.

FIG. 15 illustrates a cross section Y2 of the gate region after formation of a frontside interlayer dielectric layer, removal of the second hardmask, the dummy gate, and the sacrificial layers, formation of a gate, formation of frontside contacts, back-end-of-the-line (BEOL) layer, and the carrier wafer, in accordance with the embodiment of the present invention.

FIG. 16 illustrates a cross section X of the nanosheet transistor after flipping over the nano transistor for backside processing and the removal of the first substrate, the etch stop, and the second substrate, in accordance with the embodiment of the present invention.

FIG. 17 illustrates a cross section Y1 of the source/drain region after flipping over the nano transistor for backside processing and the removal of the first substrate, the etch stop, and the second substrate, in accordance with the embodiment of the present invention.

FIG. 18 illustrates a cross section Y2 of the gate region after flipping over the nano transistor for backside processing and the removal of the first substrate, the etch stop, and the second substrate, in accordance with the embodiment of the present invention.

FIG. 19 illustrates a cross section X of the nanosheet transistor after formation of a backside interlayer dielectric layer, in accordance with the embodiment of the present invention.

FIG. 20 illustrates a cross section Y1 of the source/drain region after formation of a backside interlayer dielectric layer, in accordance with the embodiment of the present invention.

FIG. 21 illustrates a cross section Y2 of the gate region after formation of a backside interlayer dielectric layer, in accordance with the embodiment of the present invention.

FIG. 22 illustrates a cross section X of the nanosheet transistor after formation of a second lithography layer and the formation of a contact trench in the backside interlayer dielectric layer, in accordance with the embodiment of the present invention.

FIG. 23 illustrates a cross section Y1 of the source/drain region after formation of a second lithography layer and the formation of a contact trench in the backside interlayer dielectric layer, in accordance with the embodiment of the present invention.

FIG. 24 illustrates a cross section Y2 of the gate region after formation of a second lithography layer and the formation of a contact trench in the backside interlayer dielectric layer, in accordance with the embodiment of the present invention.

FIG. 25 illustrates a cross section X of the nanosheet transistor after removal of the second lithography layer and the exposed placeholders, and the gouging of the source/drains, in accordance with the embodiment of the present invention.

FIG. 26 illustrates a cross section Y1 of the source/drain region after removal of the second lithography layer and the exposed placeholders, and the gouging of the source/drains, in accordance with the embodiment of the present invention.

FIG. 27 illustrates a cross section Y2 of the gate region after removal of the second lithography layer and the exposed placeholders, and the gouging of the source/drains, in accordance with the embodiment of the present invention.

FIG. 28 illustrates a cross section X of the nanosheet transistor after a metallization process for form a shared contact, in accordance with the embodiment of the present invention.

FIG. 29 illustrates a cross section Y1 of the source/drain region after a metallization process for form a shared contact, in accordance with the embodiment of the present invention.

FIG. 30 illustrates a cross section Y2 of the gate region after a metallization process for form a shared contact, in accordance with the embodiment of the present invention.

FIG. 31 illustrates a cross section X of the nanosheet transistor after formation of additional backside interlayer dielectric layer, a third lithography layer and formation of a signal trench, in accordance with the embodiment of the present invention.

FIG. 32 illustrates a cross section Y1 of the source/drain region after formation of additional backside interlayer dielectric layer, a third lithography layer and formation of a signal trench, in accordance with the embodiment of the present invention.

FIG. 33 illustrates a cross section Y2 of the gate region after formation of additional backside interlayer dielectric layer, a third lithography layer and formation of a signal trench, in accordance with the embodiment of the present invention.

FIG. 34 illustrates a cross section X of the nanosheet transistor after removal of the third lithography layer and the formation of backside isolation layer, in accordance with the embodiment of the present invention.

FIG. 35 illustrates a cross section Y1 of the source/drain region after removal of the third lithography layer and the formation of backside isolation layer, in accordance with the embodiment of the present invention.

FIG. 36 illustrates a cross section Y2 of the gate region after removal of the third lithography layer and the formation of backside isolation layer, in accordance with the embodiment of the present invention.

FIG. 37 illustrates a cross section Y1 of the source/drain region after formation of a signal contact, in accordance with the embodiment of the present invention.

FIG. 38 illustrates a cross section Y2 of the gate region after formation of a signal contact, in accordance with the embodiment of the present invention.

FIG. 39 illustrates a cross section X of the nanosheet transistor after formation of connecting vias, formation of a plurality of metal lines, and the formation of a backside-power-distribution-network (BSPDN), in accordance with the embodiment of the present invention.

FIG. 40 illustrates a cross section Y1 of the source/drain region transistor after formation of connecting vias, formation of a plurality of metal lines, and the formation of a backside-power-distribution-network (BSPDN), in accordance with the embodiment of the present invention.

FIG. 41 illustrates a cross section Y2 of the gate region transistor after formation of connecting vias, formation of a plurality of metal lines, and the formation of a backside-power-distribution-network (BSPDN), in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of +8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards a gate, where the gate includes a gate protrusion that extends towards the backside of a nanosheet transistor. The gate protrusion is extending between two backside contacts to connect with a backside gate signal contact. A backside gate signal contact is connected to the gate protrusion, where the backside gate single contact is isolated from the adjacent backside contacts by an isolation spacer. Furthermore, the backside surface of the backside gate single contact is on a different level than the backside surface of the backside contacts.

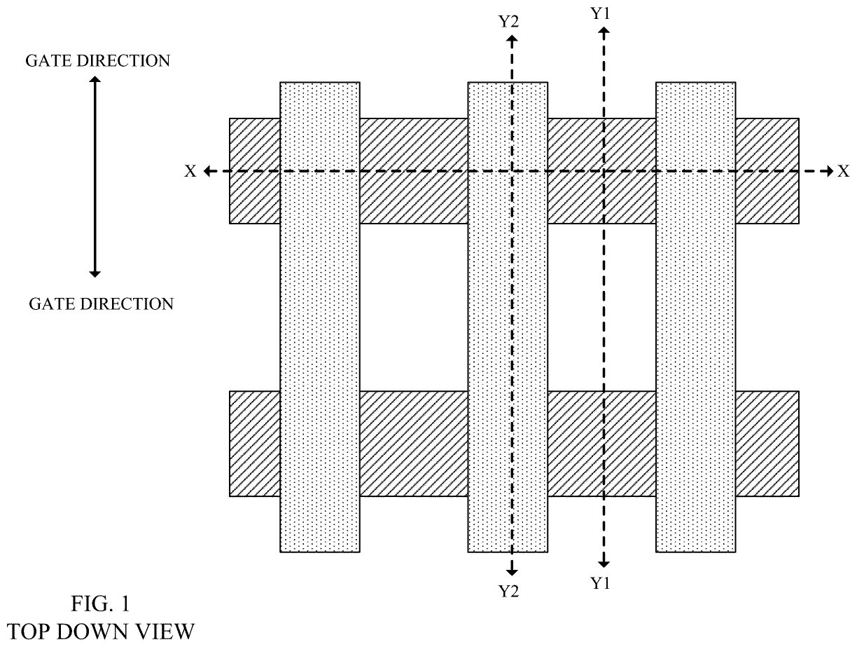

FIG. 1 illustrates a top-down view of multiple devices, in accordance with the embodiment of the present invention. The cross-section X extends horizontally through nanosheet transistors. Cross section Y1 is perpendicular to cross section X, where cross section Y1 is through a source/drain region that spans across multiple adjacent nanosheet transistors. Cross section Y2 is perpendicular to cross section X, where cross section Y2 is through a gate region that spans across multiple adjacent nanosheet transistors. Cross-section X is perpendicular to the gate direction and cross-sections Y1 and Y2 are parallel to the gate direction.

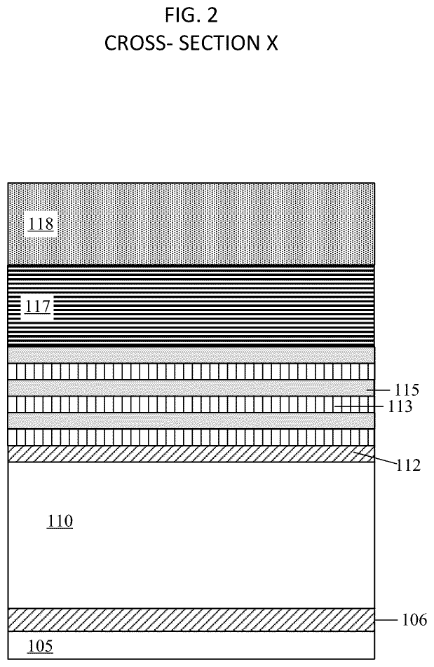

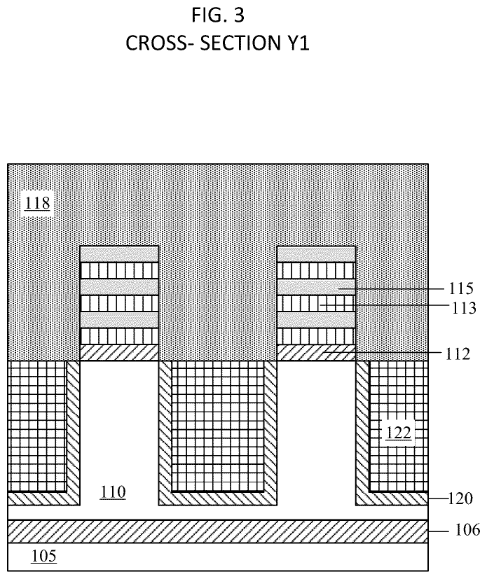

Referring now to FIGS. 2 and 3, a structure is shown during an intermediate step of a method of fabricating after the formation of a first hardmask, and a first lithography layer on top of the alternating layers, and the patterning of the first lithography layer to form the gate protrusion trench, according to an embodiment of the invention.

FIGS. 2, 3 and 4 illustrate the processing stage after the formation of a first hardmask 117, and a first lithography layer 118 on top of the alternating layers, and the patterning of the first lithography layer 118 to form the gate protrusion trench.

FIG. 2 illustrates the nano stack of the nanosheet transistors that includes a first substrate 105, an etch stop 106, a second substrate 110, a first sacrificial layer 112, alternating layers of channel layers 115 and sacrificial layers 113, a first hardmask 117, and a first lithography layer 118. The alternating layers or the nano stack is comprised of a plurality of alternating layers that include channel layers 115, and sacrificial layers 113. The plurality of channel layers 115 can be comprised of, for example, Si. The plurality of sacrificial layers 113 can be comprised of SiGe, where Ge is in the percentage of 15 to 35%. The first sacrificial layer 112 can be comprised of SiGe, where Ge is in the percentage of 50 to 75%. The higher concentration of Ge in the first sacrificial layer 112 allows for the target removal of the first sacrificial layer 112. FIG. 3 illustrates that the alternating layers or nano stack are separated into a plurality of columns. The separation of the alternating layers or nano stack into a plurality of columns causes trenches (not shown) to be formed in the second substrate 110. These trenches are filled with a first liner 120 and a shallow trench isolation layer 122.

The first substrate 105 and the second substrate 110 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of the semiconductor materials can be used as the semiconductor material of the first substrate 105 and the second substrate 110. In some embodiments, first substrate 105 and the second substrate 110 includes both semiconductor materials and dielectric materials. The semiconductor first substrate 105 and the second substrate 110 may also comprise an organic semiconductor or a layered semiconductor such as, for example, Si/SiGe, a silicon-on-insulator or a SiGe-on-insulator. A portion or the entire semiconductor first substrate 105 and the second substrate 110 may also be comprised of an amorphous, polycrystalline, or monocrystalline. The semiconductor first substrate 105 and the second substrate 110 may be doped, undoped or contain doped regions and undoped regions therein.

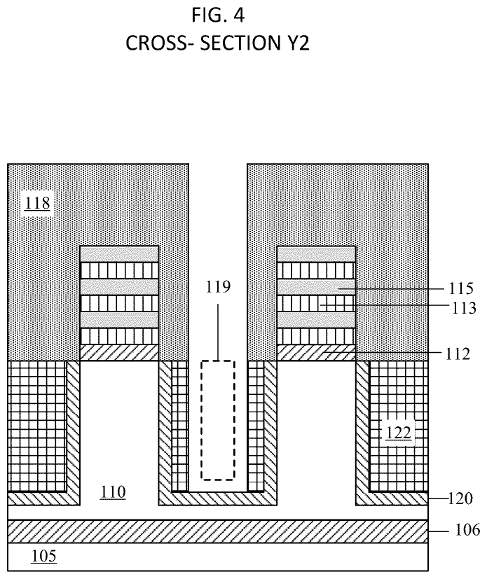

FIG. 4 illustrates the formation of the gate protrusion trench 119. The first lithography layer 118 and the shallow trench isolation layer 122 are patterned to create a gate protrusion trench 119 in the shallow trench isolation layer 122. Gate protrusion trench 119 is located between nano stack columns.

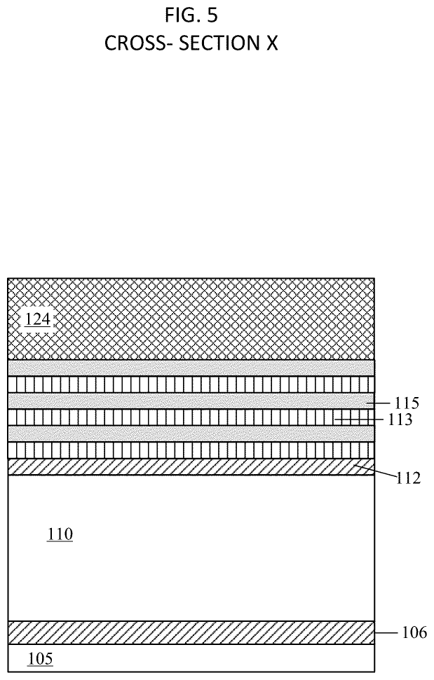

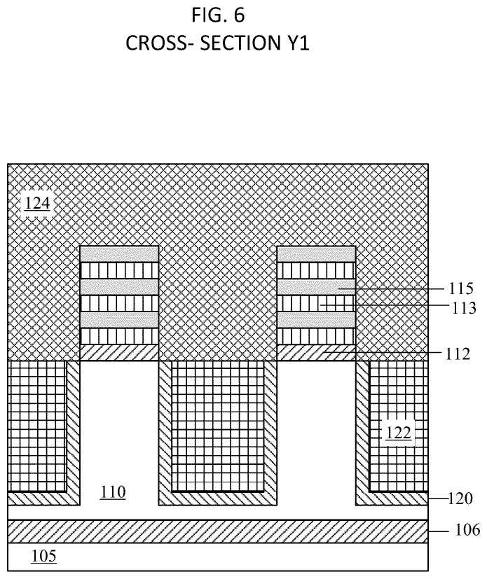

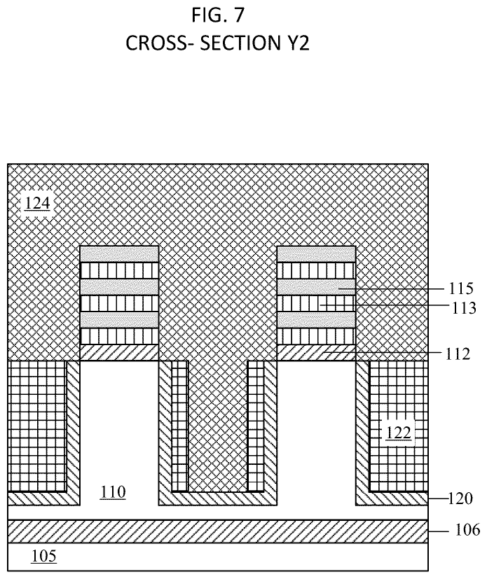

FIGS. 5, 6 and 7 illustrate the processing stage after the removal of the first lithography layer 118 and the removal of the first hardmask 117 and the formation of a dummy gate 124. The first lithography layer 118 and the first hardmask 117 are removed to expose the underlying nanosheet stacks (or nano stacks). Dummy gate 124 is formed on top of and around the nanosheet stacks as illustrated in FIGS. 5-7. Dummy gate 124 fills gate protrusion trench 119, thus forming a dummy gate 124 protrusion towards the backside of the device, as illustrated in FIG. 7.

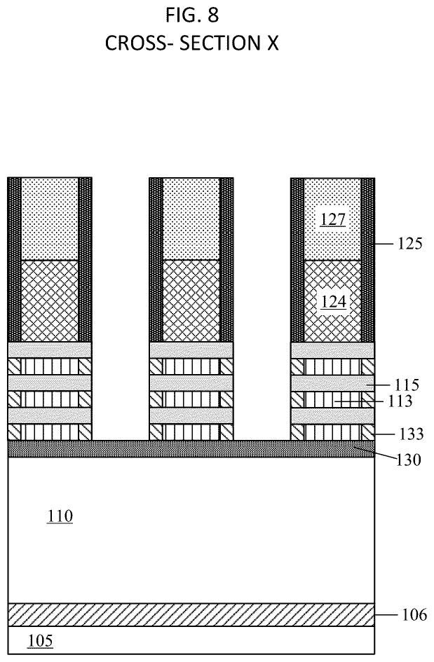

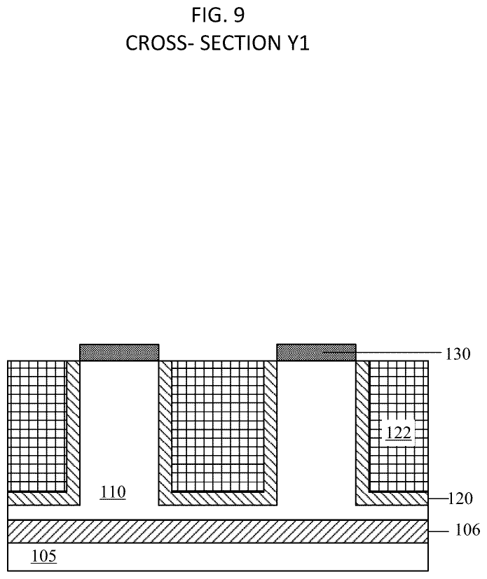

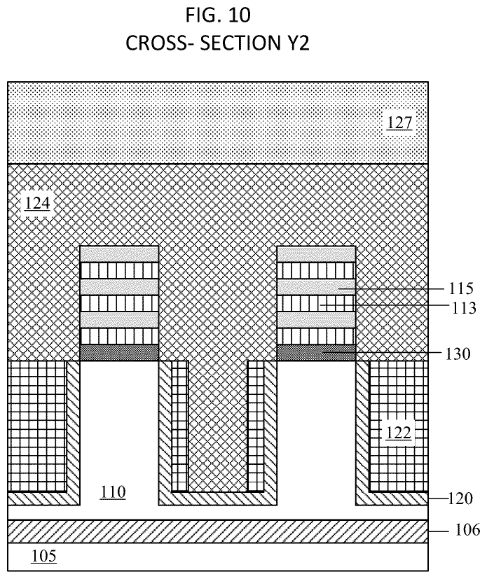

FIGS. 8, 9 and 10 illustrate the processing stage after the formation of a second hardmask 127, removal of the first sacrificial layer 112, formation of the gate spacer 125 and the bottom dielectric isolation layer 130, patterning of the nano stacks to form the source/drain regions, recessing of the sacrificial layers 113, and formation of the inner spacer 133. A second hardmask 127 is formed on top of dummy gate 124. The second hardmask 127 and the dummy gate 124 are patterned to form a plurality of columns on top of the nano stack. The first sacrificial layer 112 is selectively removed. A bottom dielectric isolation layer 130 is formed in the location of the removed first sacrificial layer 112. Gate spacer 125 is formed adjacent to each of the dummy gate 124 and second hardmask 127 columns. The underlying alternating layers, nanosheet stack, or nano stack is etched to separate the alternating layers into a plurality of columns, where each of the columns is separated by a source/drain region. The sacrificial layers 113 in each of the nano stack columns is recessed to form an empty cavity and this cavity is filled with a material to form the inner spacer 133. FIG. 9 illustrates the removal of the alternating layers to form the source/drain region and FIG. 10 illustrates that the gate region is protected by the second hardmask 127.

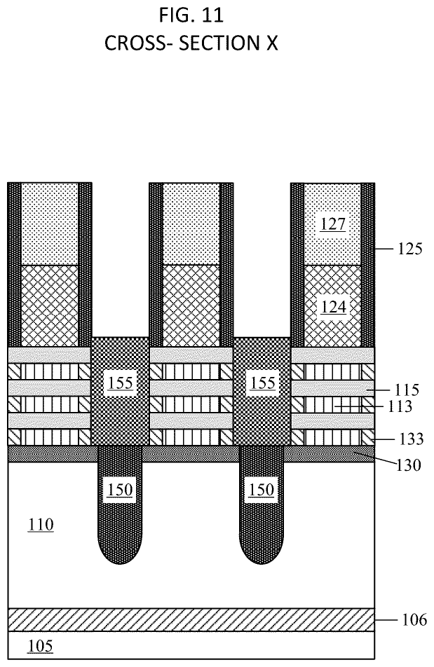

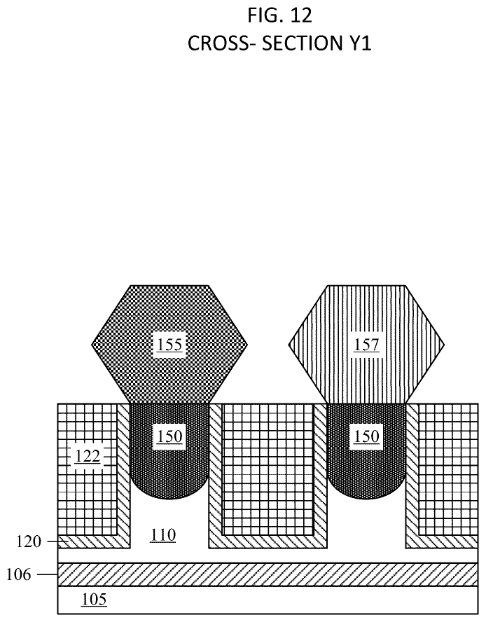

FIGS. 11 and 12 illustrate the processing stage after the formation of placeholders 150 and the formation of the source/drains 155, 157. Trenches (not shown) are formed in the second substrate 110 in the source/drain regions. These trenches are filled with a material to form placeholder 150. Source/drain 155, 157 are epitaxially grown in the source/drain regions above the placeholders 150. The source/drains 155, 157 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques. A frontside interlayer dielectric layer 165 is formed on top of the source/drains epis 155, 157, on top of the shallow trench isolation layer 122, and around the gate spacer 125. The hardmask 127 is removed to expose the underlying dummy gate 124.

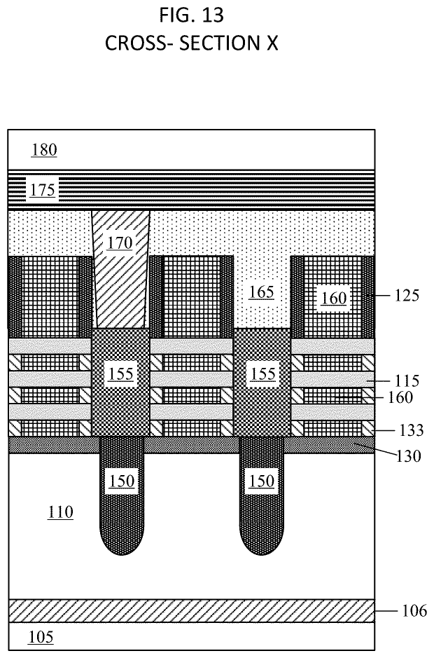

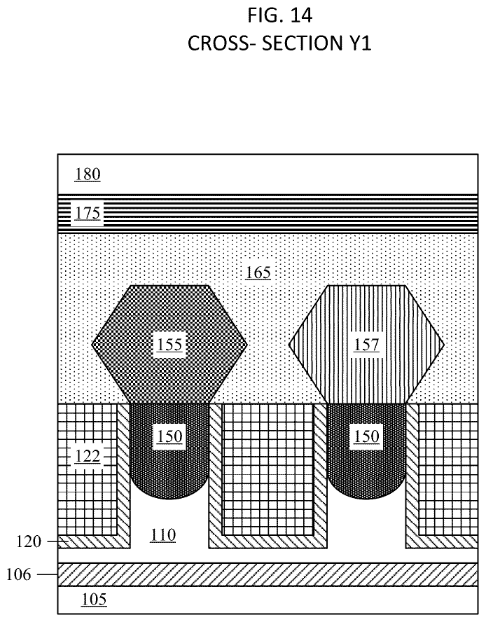

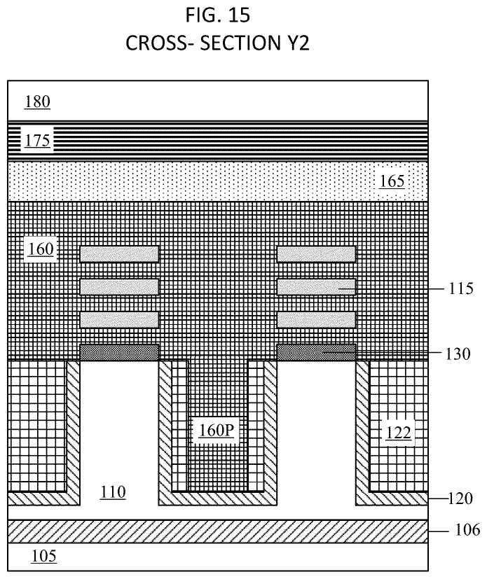

FIGS. 13, 14 and 15 illustrate the processing stage after formation of a frontside interlayer dielectric layer 165, removal of the second hardmask 127, the dummy gate 124, and the sacrificial layers 113, formation of a gate 160, formation of frontside contacts 170, back-end-of-the-line (BEOL) layer 175, and the carrier wafer 180. A frontside interlayer dielectric layer 165 is formed on top of the source/drains 155. The second hardmask 127, the dummy gate 124, and the sacrificial layers 113 are removed. Gate 160 is formed in the space created by the removal of the dummy gate 124 and the sacrificial layers 113. Gate 160 is formed in this empty space. Gate 160 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W. As seen in FIG. 15, gate 160 includes gate protrusion 160P that extends towards the backside of the nanosheet transistor.

Additional frontside interlayer dielectric layer 165 material is added to extend the frontside interlayer dielectric layer 165 on top of gate 160. A trench (not shown) is formed in the frontside interlayer dielectric layer 165 and filled with a conductive metal to form the frontside contact 170. Back-end-of-the-line (BEOL) layer 175 is formed on top of the frontside interlayer dielectric layer 165 and the frontside contact 170. A carrier wafer 180 is attached to the BEOL layer 175 to allow for the nano device/nano transistor to be flipped over for backside processing.

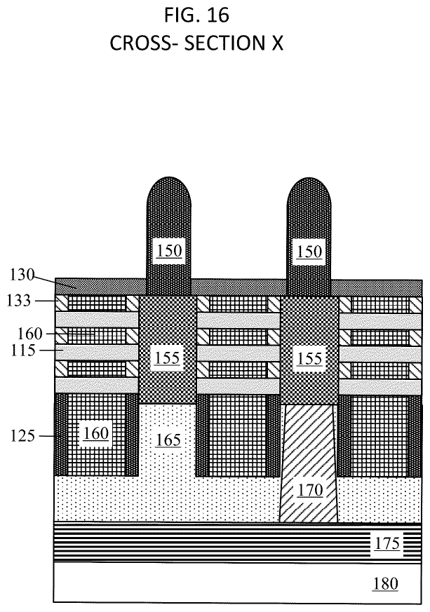

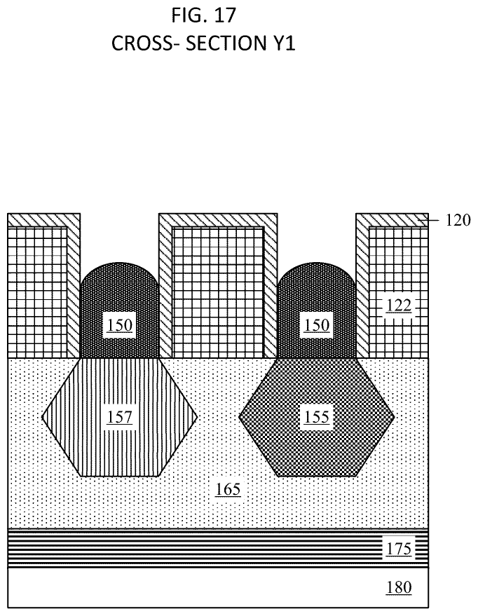

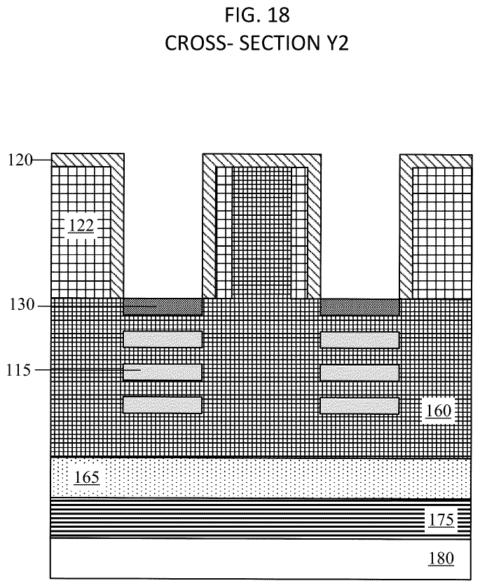

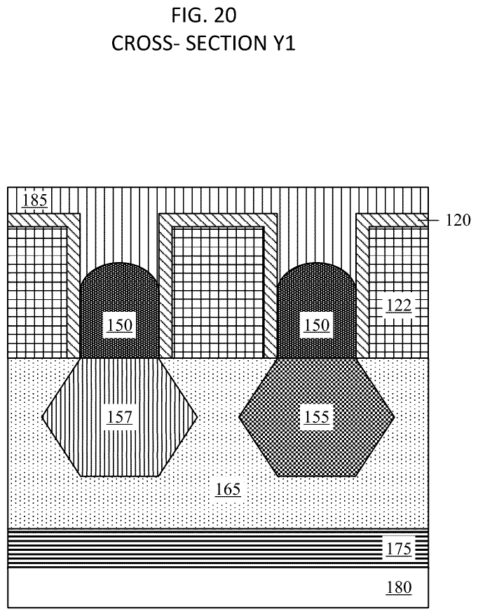

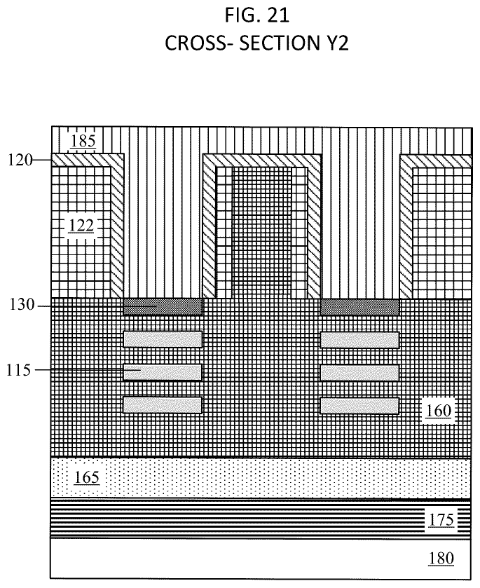

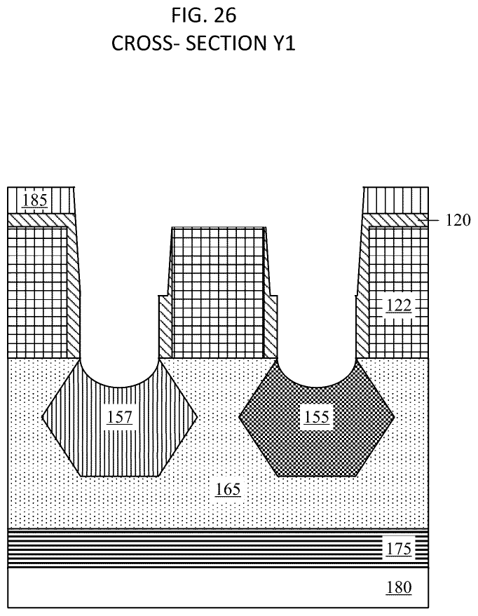

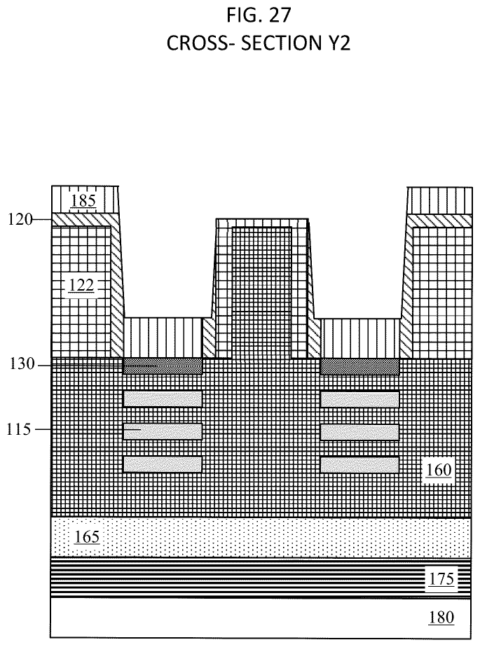

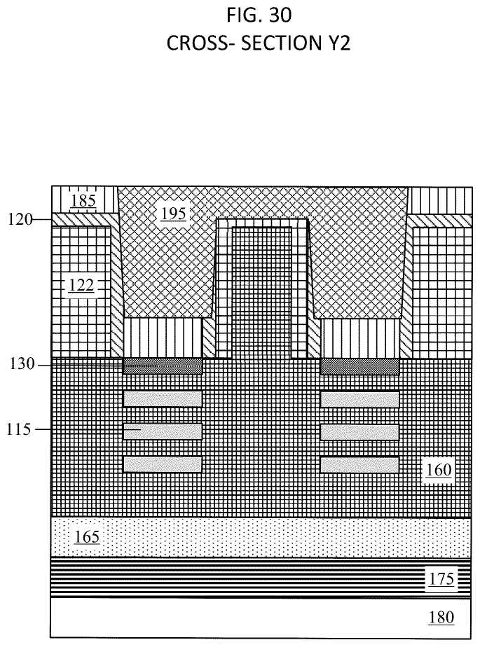

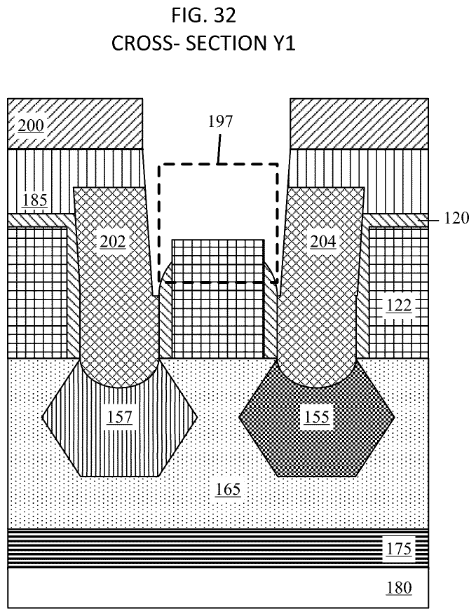

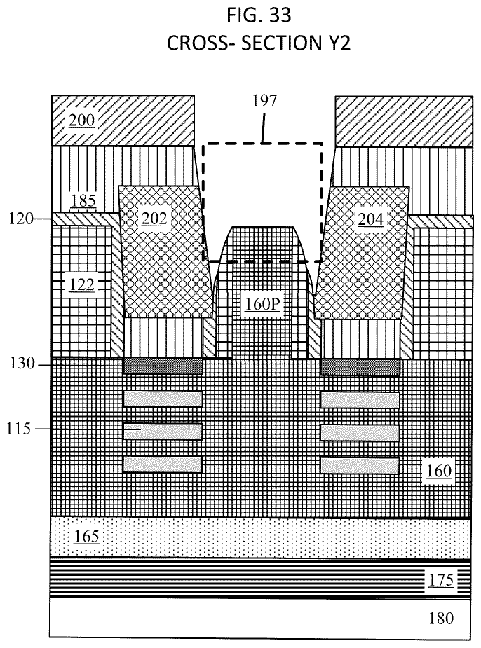

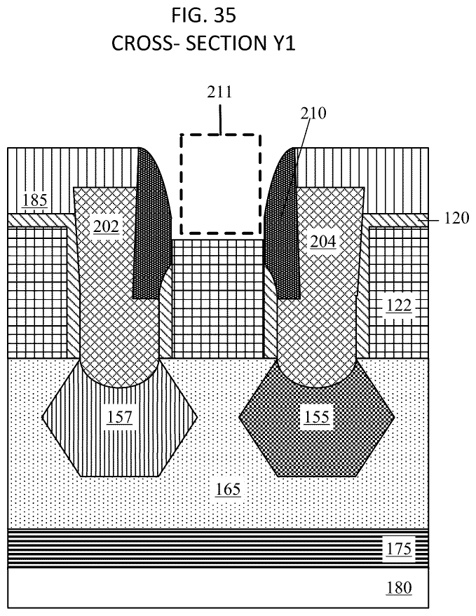

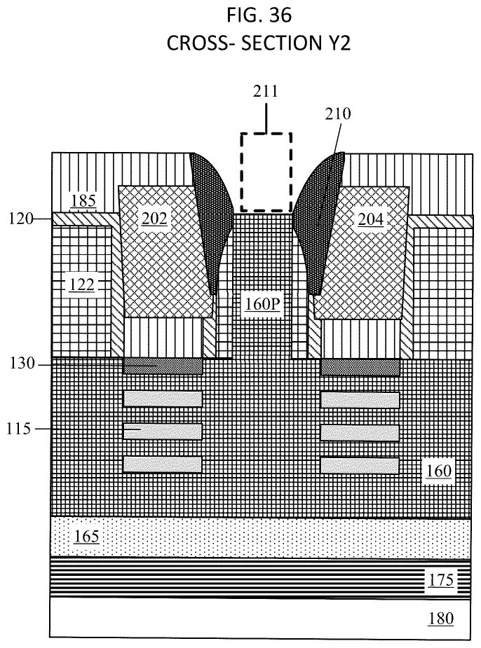

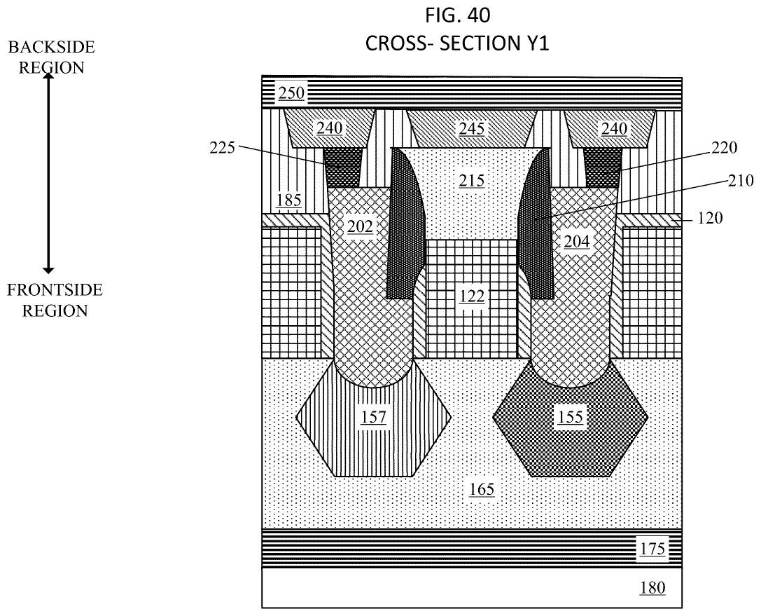

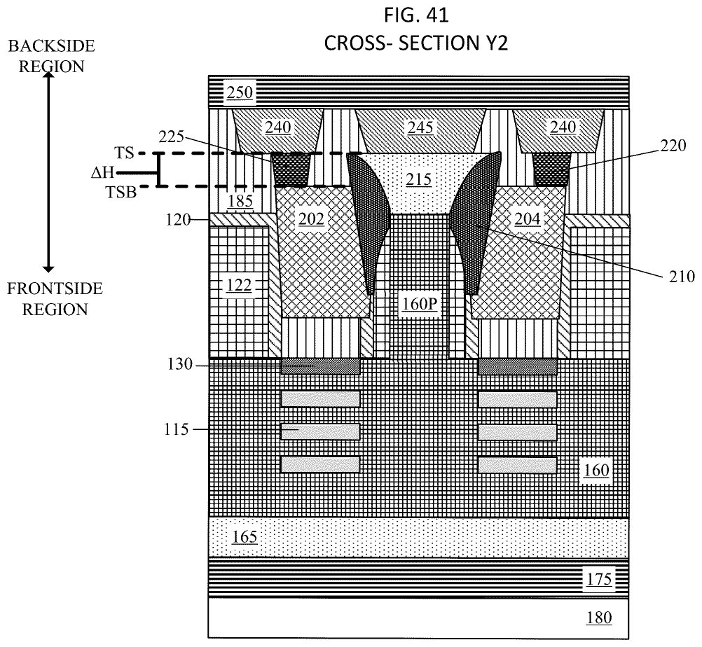

FIGS. 16, 17 and 18 illustrate the processing stage after flipping over the nano transistor for backside processing and the removal of the first substrate 105, the etch stop 106, and the second substrate 110. FIGS. 2-15 illustrate the frontside processing of the nano transistor while FIGS. 16-41 illustrate the backside processing of the nano transistor. The first substrate 105, the etch stop 106, and the second substrate 110 is removed to expose the placeholders 150, a backside surface of the bottom dielectric isolation layer 130, and a surface of the liner 120.

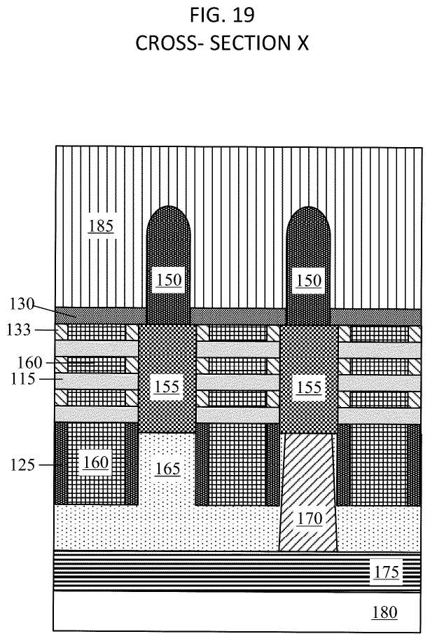

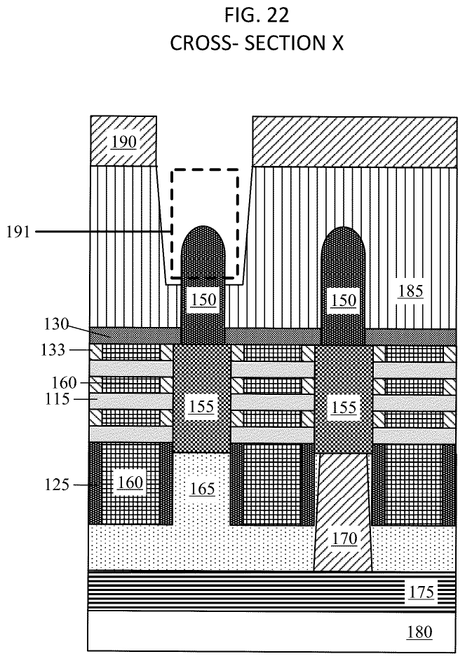

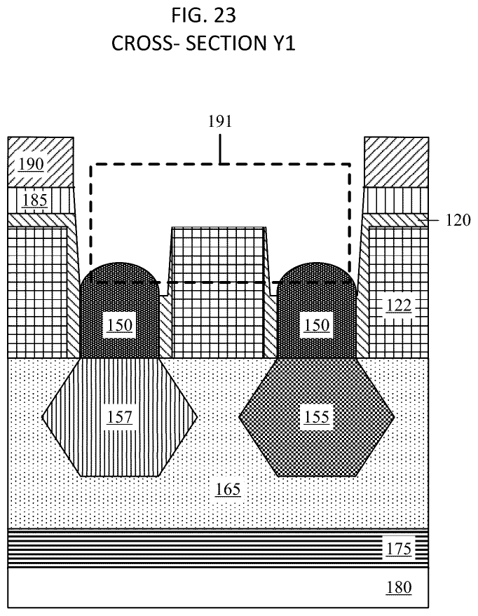

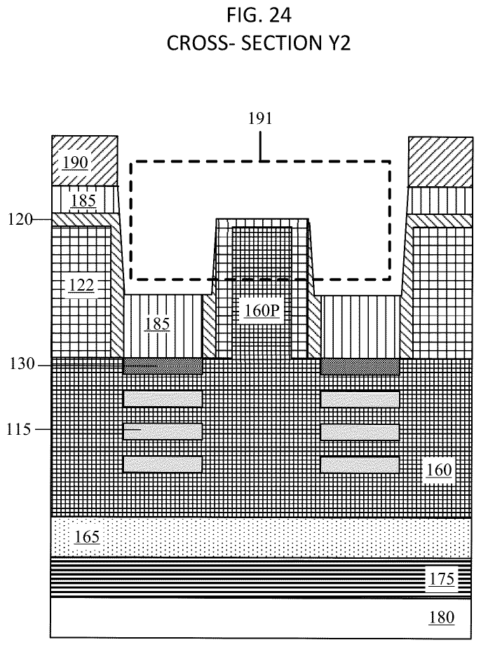

FIGS. 19, 20 and 21 illustrate the processing stage after formation of a backside interlayer dielectric layer 185. A backside interlayer dielectric layer 185 forms on top of the bottom dielectric isolation layer 130, around the placeholders 150, and on top of liner 120. FIGS. 22, 23 and 24 illustrate the processing stage after formation of a second lithography layer 190 and the formation of contact trench 191 in the backside interlayer dielectric layer 185. A second lithography layer 190 is formed on top of the backside interlayer dielectric layer 185. The second lithography layer 190 and the backside interlayer dielectric layer 185 are patterned to form the contact trench 191. As illustrated in FIG. 22 the contact trench 191 exposes placeholder 150 located on the backside surface of source/drain 155. FIG. 23 illustrates that the contact trench 191 extends between adjacent nano transistors, such that, contact trench 191 exposes the placeholder 150 located on the backside of source/drain 155 and 157. FIG. 24 illustrates that the contact trench 191 extends around gate protrusion 160P.

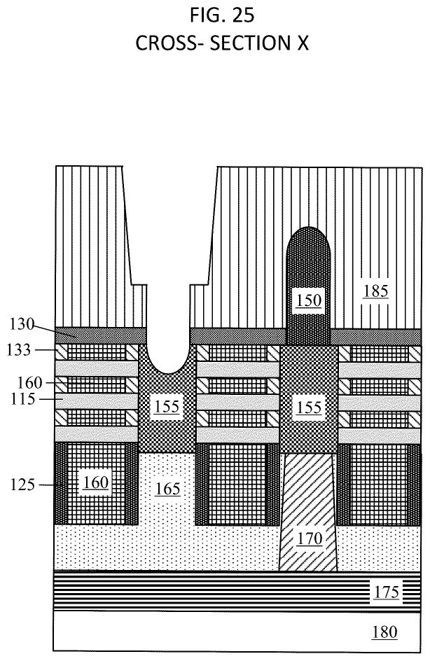

FIGS. 25, 26 and 27 illustrate the processing stage after removal of the second lithography layer 190 and the exposed placeholders 150, and the gouging of the source/drains 155, 157. The second lithography layer 190 and the placeholder 150 exposed by the contact trench 191 are removed to expose the backside surfaces of the source/drains 155, 157. The figures show an optional process of gouging of the source/drains 155, 157.

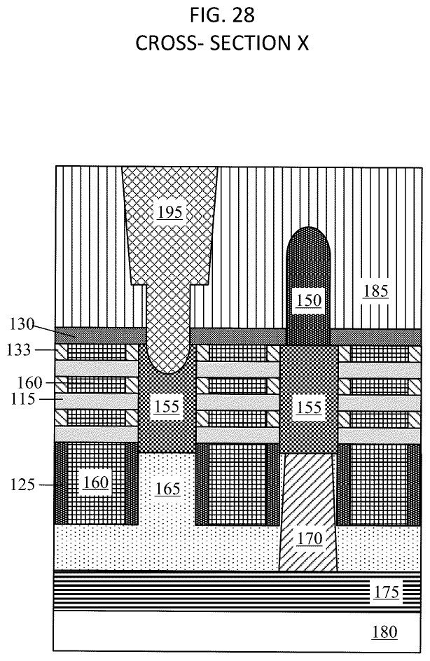

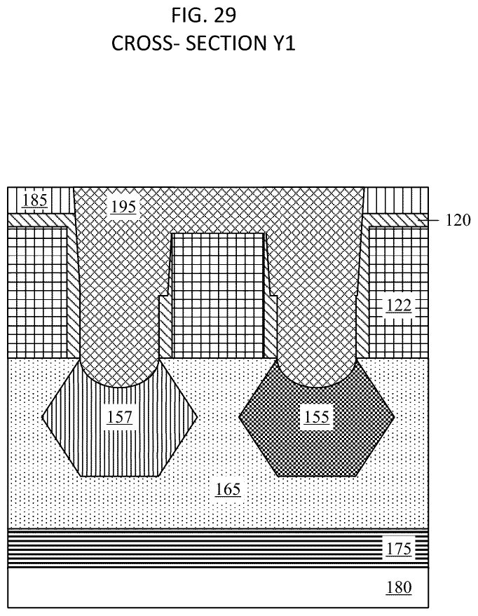

FIGS. 28, 29 and 30 illustrate the processing stage after a metallization process to form a shared contact 195. Contact trench 191 is filled with a conductive metal via a metallization process to form the shared contact 195. Shared contact 195 is in contact with a backside surface of multiple source/drains 155, 157, as illustrated in FIGS. 28 and 29.

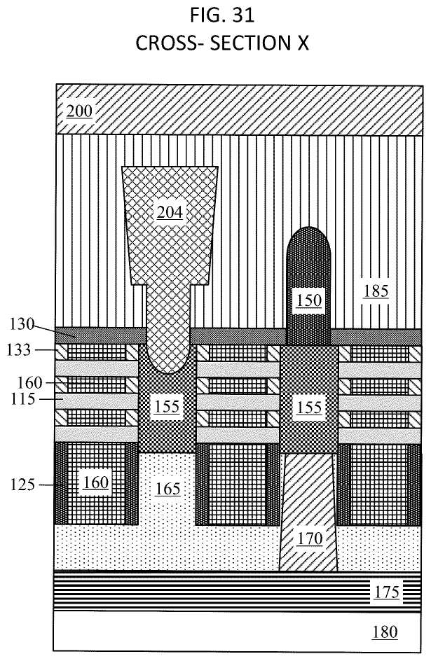

FIGS. 31, 32 and 33 illustrate the processing stage after formation of additional backside interlayer dielectric layer 185, a third lithography layer 200 and formation of a signal trench 197. The height of the backside interlayer dielectric layer 185 is increased such that the backside interlayer dielectric layer extends over the shared contact 195. A third lithography layer 200 is formed on top of the backside interlayer dielectric layer 185. The signal trench 197 is formed in the third lithography layer 200, the backside interlayer dielectric layer 185, and the shared contact 195. The signal trench 197 separates the shared contact 195 into a first backside contact 202 and a second backside contact 204. The first backside contact 202 is in contact with a backside surface of source/drain 157. The second backside contact 204 is in contact with a backside surface of source/drain 155. Signal trench 197 exposes portions of the shallow trench isolation layer 122 and a backside surface of the gate protrusion 160P.

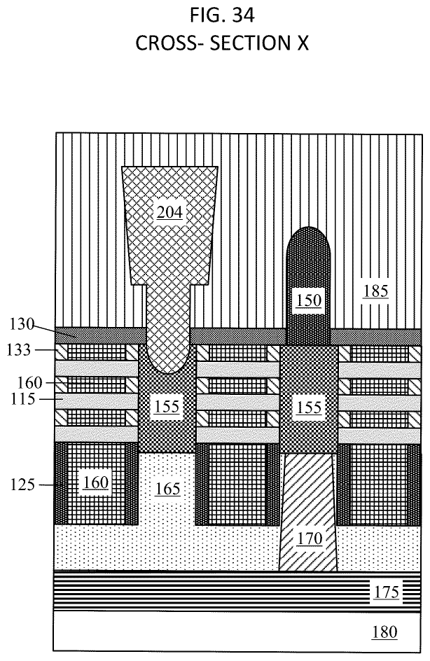

FIGS. 34, 35 and 36 illustrate the processing stage after removal of the third lithography layer 200 and the formation of backside isolation layer 210. The third lithography layer 200 is removed and a backside isolation layer 210 is formed along the side boundaries of the signal trench 197. Each vertical segment of the backside isolation layer 210 is in contact with a different backside contact 202, 204. The backside isolation layer 210 narrows the signal trench 197 to form the narrow signal trench 211.

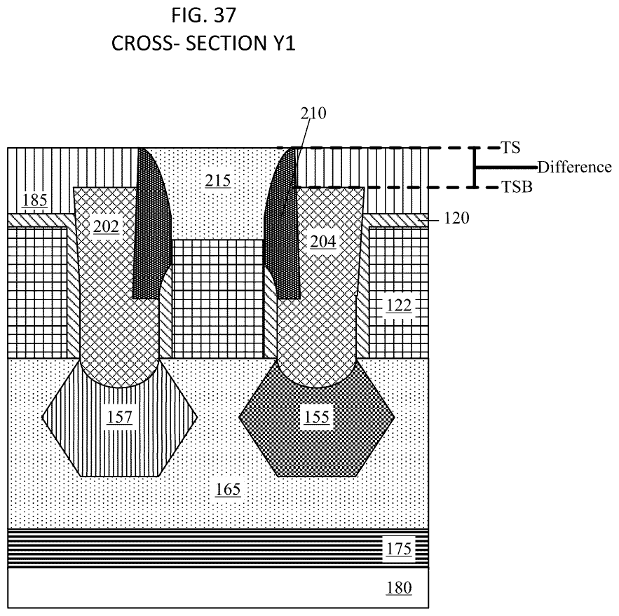

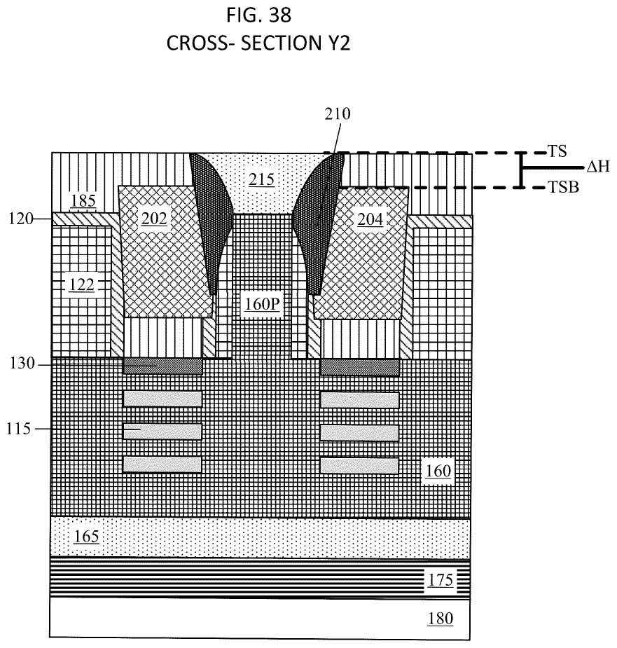

FIGS. 37 and 38 illustrate the processing stage after formation of a signal contact 215. Signal contact 215 is formed by filling the narrow signal trench 197 with a conductive metal via a metallization process. Signal contact 215 is in contact with multiple vertical segments of the backside isolation layer 210. The backside isolation layer 210 is located between the signal contact 215 and first and second backside contacts 202, 204, respectively. The top surface TS of the signal contact 215 is on a different level than the top surface TSB of the backside contacts 202, 204. Alternatively, another way to describe it, there is a height difference ΔH between the top surface TS of the signal contact 215 and the top surface TSB of the backside contacts 202, 204.

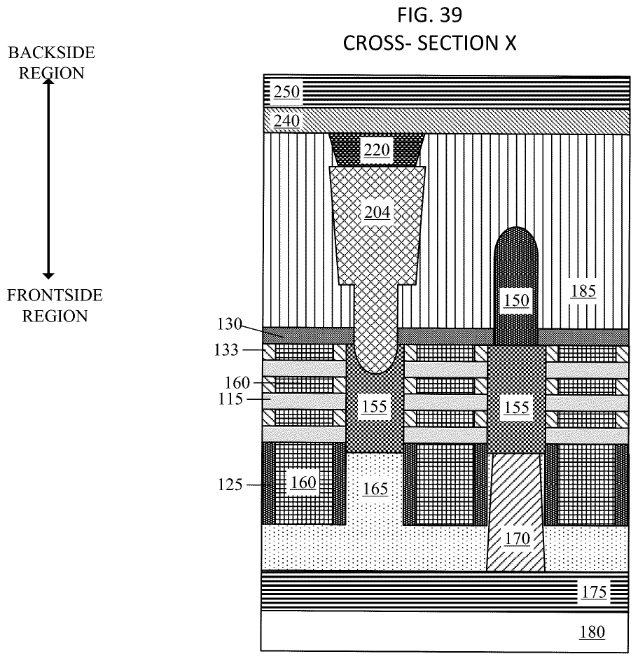

FIGS. 39, 40 and 41 illustrate the processing stage transistor after formation of connecting vias 220, 225, formation of a plurality of metal lines 240, 245, and the formation of a backside-power-distribution-network (BSPDN) 250. A plurality of trenches (not shown) are formed in the backside interlayer dielectric layer 185 and filled with a conductive metal to form a plurality of connecting vias 220, 225. Each of the connecting vias 220, or 225 extends down to one of the backside contacts 202, 204, respectively. The top surface of each of the connecting vias 220, 225 is substantially at the same height/level as the top surface TS of the signal contact 215. Trenches (not shown) are formed in the backside interlayer dielectric layer 185 and filled with a conductive metal to form a plurality of metal lines 240, 245. For example, metal lines 240 can be VSS or VDD buried power rails and metal line 245 can be a signal line. A backside-power-distribution-network (BSPDN) 250 is formed on the top surface of metal lines 240, 245 and on top of the backside interlayer dielectric layer 185.

A microelectronic structure a first nanosheet transistor that includes a first source/drain 157, and a second nanosheet transistor that is adjacent to the first nanosheet transistor. The second nanosheet transistor includes a second source/drain 155. A shared gate 160 that extends between the first nanosheet transistor and the second nanosheet transistor. A gate protrusion 160P that extends towards a backside region of the first nanosheet transistor and the backside region of the second nanosheet transistor. A first backside contact 202 connected to first source/drain 157 and a second backside contact 204 connected to the second source/drain 155. A signal contact 215 connected to the gate protrusion 160P. An isolation layer 210 located between the signal contact 215 and first backside contact 202 and the isolation layer 210 is located between the signal contact 215 and the second backside contact 204.

A top surface TSB of the first backside contact 202 and a top surface TS of the signal contact 215 are on different levels.

A signal line 245 in direct contact with a top surface TS of the signal contact 215.

The isolation layer 210 extends higher than a top surface TSB of the first backside contact 202 or a top surface TS of the second backside contact 204.

A shallow trench isolation layer 122 located between the first backside contact 202 and the second backside contact 204. The signal contact 215 is in contact with a top surface of the shallow trench isolation layer 122. A first sidewall of the isolation layer 210 is in contact with both the shallow trench isolation layer 122 and the signal contact 215. A backside interlayer dielectric layer 185 located above the first backside contact 202 and the second backside contact 204. A second sidewall of the isolation layer 210 is in contact with the backside interlayer dielectric layer 185 and the first backside contact 202 or the second backside contact 204, respectively.

A microelectronic structure a first nanosheet transistor that includes a first source/drain 157, and a second nanosheet transistor that is adjacent to the first nanosheet transistor. The second nanosheet transistor includes a second source/drain 155. A shared gate 160 that extends between the first nanosheet transistor and the second nanosheet transistor. A gate protrusion 160P that extends towards a backside region of the first nanosheet transistor and the backside region of the second nanosheet transistor. A first backside contact 202 connected to first source/drain 157 and a second backside contact 204 connected to the second source/drain 155. A first metal line 240 connected to the first backside contact 202 and a second metal line 240 connected to the second backside contact 204. A signal contact 215 connected to the gate protrusion 160P. An isolation layer 210 located between the signal contact 215 and first backside contact 202 and the isolation layer 210 is located between the signal contact 215 and the second backside contact 204.

A top surface TSB of the first backside contact 202 and a top surface TS of the signal contact 215 are on different levels.

A signal line 245 in direct contact with a top surface TS of the signal contact 215. The signal line 245, the first metal line 240 and the second metal line 240 are on the same level. A first connecting via 225 connecting the first metal line 240 to the first backside contact 202. A second connecting via 220 connecting the second metal line 240 to the second backside contact 204. The isolation layer 210 extends higher than a top surface TSB of the first backside contact 202 or a top surface TSB of the second backside contact 204. A shallow trench isolation layer 122 located between the first backside contact 202 and the second backside contact 204.

A first sidewall of the isolation layer 210 is in contact with both the shallow trench isolation layer 122 and the signal contact 215. A backside interlayer dielectric layer 185 located above the first backside contact 202 and the second backside contact 204. A second sidewall of the isolation layer 210 is in contact with the backside interlayer dielectric layer 185 and the first backside contact 202 or the second backside contact 204, respectively.

A method includes the steps of forming a first nanosheet transistor that includes a first source/drain 157, and forming a second nanosheet transistor that is adjacent to the first nanosheet transistor. The second nanosheet transistor includes a second source/drain 155. Forming a shared gate 160 that extends between the first nanosheet transistor and the second nanosheet transistor. Forming a gate protrusion 160P that extends towards a backside region of the first nanosheet transistor and the backside region of the second nanosheet transistor. Forming a shared backside contact 195 separating the shared backside contact 195 into a first backside contact 202 connected to first source/drain 157 and a second backside contact 204 connected to the second source/drain 155. Forming a first isolation layer 210 segment adjacent to the first backside contact 202 and forming a second isolation layer segment 210 adjacent to the second backside contact 204. Forming a signal contact 215 connected to the gate protrusion 160P, wherein the signal contact 215 is located between the first isolation layer segment 210 and the second isolation layer segment 210.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a first nanosheet transistor that includes a first source/drain;
a second nanosheet transistor that is adjacent to the first nanosheet transistor, wherein the second nanosheet transistor includes a second source/drain;
a shared gate that extends between the first nanosheet transistor and the second nanosheet transistor;
a gate protrusion that extends towards a backside region of the first nanosheet transistor and the backside region of the second nanosheet transistor;
a first backside contact connected to the first source/drain and a second backside contact connected to the second source/drain;
a signal contact connected to the gate protrusion; and
an isolation layer located between the signal contact and first backside contact and the isolation layer is located between the signal contact and the second backside contact.

2. The microelectronic structure of claim 1, wherein a top surface of the first backside contact and a top surface of the signal contact are on different levels.

3. The microelectronic structure of claim 1, further comprising:
a signal line in direct contact with a top surface of the signal contact.

4. The microelectronic structure of claim 1, wherein the isolation layer extends higher than a top surface of the first backside contact or a top surface of the second backside contact.

5. The microelectronic structure of claim 4, further comprising:
a shallow trench isolation layer located between the first backside contact and the second backside contact.

6. The microelectronic structure of claim 5, wherein the signal contact is in contact with a top surface of the shallow trench isolation layer.

7. The microelectronic structure of claim 6, a first sidewall of the isolation layer is in contact with both the shallow trench isolation layer and the signal contact.

8. The microelectronic structure of claim 7, further comprising:
a backside interlayer dielectric layer located above the first backside contact and the second backside contact.

9. The microelectronic structure of claim 8, wherein a second sidewall of the isolation layer is in contact with the backside interlayer dielectric layer and the first backside contact or the second backside contact, respectively.

10. A microelectronic structure comprising:
a first nanosheet transistor that includes a first source/drain;
a second nanosheet transistor that is adjacent to the first nanosheet transistor, wherein the second nanosheet transistor includes a second source/drain;
a shared gate that extends between the first nanosheet transistor and the second nanosheet transistor;
a gate protrusion that extends towards a backside region of the first nanosheet transistor and the backside region of the second nanosheet transistor;
a first backside contact connected to the first source/drain and a second backside contact connected to the second source/drain;
a first metal line connected to the first backside contact and a second metal line connected to the second backside contact;
a signal contact connected to the gate protrusion; and
an isolation layer located between the signal contact and first backside contact and the isolation layer is located between the signal contact and the second backside contact.

11. The microelectronic structure of claim 10, wherein a top surface of the first backside contact and a top surface of the signal contact are on different levels.

12. The microelectronic structure of claim 11, further comprising:
a signal line in direct contact with a top surface of the signal contact.

13. The microelectronic structure of claim 12, wherein the signal line, the first metal line and the second metal line are on the same level.

14. The microelectronic structure of claim 13, further comprising:
a first connecting via connecting the first metal line to the first backside contact; and
a second connecting via connecting the second metal line to the second backside contact.

15. The microelectronic structure of claim 14, wherein the isolation layer extends higher than a top surface of the first backside contact or a top surface of the second backside contact.

16. The microelectronic structure of claim 15, further comprising:
a shallow trench isolation layer located between the first backside contact and the second backside contact.

17. The microelectronic structure of claim 16, a first sidewall of the isolation layer is in contact with both the shallow trench isolation layer and the signal contact.

18. The microelectronic structure of claim 17, further comprising:
a backside interlayer dielectric layer located above the first backside contact and the second backside contact.

19. The microelectronic structure of claim 18, wherein a second sidewall of the isolation layer is in contact with the backside interlayer dielectric layer and the first backside contact or the second backside contact, respectively.

20. A method comprising:
forming a first nanosheet transistor that includes a first source/drain;
forming a second nanosheet transistor that is adjacent to the first nanosheet transistor, wherein the second nanosheet transistor includes a second source/drain;
forming a shared gate that extends between the first nanosheet transistor and the second nanosheet transistor;
forming a gate protrusion that extends towards a backside region of the first nanosheet transistor and the backside region of the second nanosheet transistor;
forming a shared backside contact separating the shared backside contact into a first backside contact connected to the first source/drain and a second backside contact connected to the second source/drain;
forming a first isolation layer segment adjacent to the first backside contact and forming a second isolation layer segment adjacent to the second backside contact; and
forming a signal contact connected to the gate protrusion, wherein the signal contact is located between the first isolation layer segment and the second isolation layer segment.
